(19) United States
(12) Patent Application Publication
(10) Pub. No.: US 2022/0235448 A1
(43) Pub. Date: Jul. 28, 2022

(54) METHOD FOR VACUUM COATING A COLORFUL FILM

(71) Applicant: Jinhua Enjoy & Wonderful Inc., Jinhua (CN)

(72) Inventors: Yiwei ZHANG, Jihua (CN); Shijie XU, Jinhua (CN)

(21) Appl. No.: 17/612,563

(22) PCT Filed: Aug. 28, 2020
(86) PCT No.: PCT/CN2020/112127

§ 371 Date: Nov. 18, 2021

(30) Foreign Application Priority Data
Oct. 18, 2019 (CN) 2019 10994821.4

(51) Int. Cl. C23C 14/00; C23C 14/02; C23C 14/06; C23C 14/24

(52) U.S. Cl. CPC C23C 14/0015; C23C 14/022; C23C 14/24; C23C 14/0694; C23C 14/0629

(57) ABSTRACT

A method for vacuum coating a colorful film includes the following steps: pre-treating a substrate; cleaning an evaporation chamber; placing the substrate and evaporation sources; performing a pre-vacuuming; performing an ion cleaning; performing a fine vacuuming; performing evaporation operations; completing the evaporation operations. When performing evaporation operations, the first and the second evaporation materials are pre-melted; and then the evaporation operations are carried out alternately after pre-melting, with a total time of the evaporation operation of 1000-1200 seconds. The finished film has four layers, from the inside to the outside, the four layers are a first coating layer, a second coating layer, a third coating layer and a fourth coating layer; the first coating layer and the third coating layer have a same material, and the second coating layer and the fourth coating layer have another same material.

### TECHNICAL FIELD

The present disclosure belongs to the technical field of vacuum coating, and specifically relates to a method for vacuum coating a colorful film.

### BACKGROUND

Most plastic products have defects such as low surface hardness, insufficient appearance, and low wear resistance. The quality of plastic products can be improved by coating, so that they can have metallic luster and higher hardness, and the color is more gorgeous. Evaporation is a process commonly used in vacuum coating. By heating and evaporating metal or metal compounds to deposit on the surface of the substrate, plastic products have a metallic luster. By evaporating different evaporation materials, coatings with different colors can be deposited on the plastic tableware. However, the existing coating's color is monotonous and not rich enough to meet the individual needs of customers

### SUMMARY

The present disclosure is intended to address the problem of monotonous color of coated products in the prior art, which is not rich and gorgeous enough to meet the individual needs of customers, and provides a method for vacuum coating a colorful film, such that the coated product can obtain colorful effects with rich and gorgeous colors.

The object of the present disclosure can be achieved through the following technical solutions:

A method for vacuum coating a colorful film, comprising the following steps:

Step 1: pre-treating a substrate;

scrubbing the substrate with acetone, dehydrating the substrate with absolute ethanol, and then drying the substrate for later use;

Step 2: cleaning an evaporation chamber;

removing dusts from the evaporation chamber, and then scrubbing an inside of the evaporation chamber with the acetone and alcohol;

Cleaning the evaporation chamber before evaporation can improve the purity of the film and the bonding force of the film base;

Step 3: placing the substrate and evaporation sources;

placing the substrate on a substrate holder, placing a first evaporation material on a first evaporation source, and placing a second evaporation material on a second evaporation source, providing a shutter between the first evaporation source and the second evaporation source, closing the evaporation chamber to form an enclosed evaporation space;

Step 4: performing a pre-vacuuming;

turning on an exhaust pump to exhaust the enclosed evaporation chamber, so that a vacuum degree of the evaporation chamber reaches 0.2-0.4 Pa;

Step 5: performing an ion cleaning;

filling the evaporation chamber with argon gas, and performing ion bombardment on the substrate under a high pressure of 5000V with a bombardment time of 5-10 min; rotating the substrate holder during an ion bombardment process;

The present disclosure performs ion cleaning on the substrate before coating, can maintain the chemical purity of the substrate, ensure the coating effect, and will not produce a damage layer on the surface. The surface quality can be guaranteed. Because it is performed in a vacuum, it does not pollute the environment, it is ensured that the substrate is not secondarily contaminated.

Step 6: performing a fine vacuuming;

pumping the enclosed evaporation chamber again by using an air pump, to make the vacuum degree in the evaporation chamber reach 0.001-0.003 Pa;

Appropriate vacuum can greatly reduce the evaporation temperature of the evaporation material and improve the evaporation efficiency.

Step 7: performing evaporation operations;

pre-melting the first evaporation material and the second evaporation material with a pre-melting time of 50-60 seconds and a pre-melting temperature of 1000-1200° C.; performing evaporation operations alternately after pre-melting; a total time of the evaporation operation is 1000-1200 seconds;

Step 8: completing the evaporation operations;

placing the substrate in the evaporation chamber for 8-12 minutes after the evaporation operations are completed, and then closing each system; inflating the evaporation chamber, to balance air pressures inside and outside the evaporation chamber; taking out the substrate;

wherein a finished film has four layers, from an inside to an outside, the four layers comprises a first coating layer, a second coating layer, a third coating layer and a fourth coating layer; the first coating layer and the third coating layer have a same material, and the second coating layer and the fourth coating layer have another same material.

The light can be reflected and refracted on the multi-layer coating, and the reflected light is superimposed on each other, so that the colorful film has a high reflectivity as a whole, so as to achieve the colorful effect. The four-layer coating can be obtained by alternate evaporation of two kinds of evaporation materials, while reducing the production cost, the difficulty of operation is reduced, and the purity of the coating is easy to guarantee, and the colorful effect is good.

In a preferred embodiment, the first evaporation material is magnesium fluoride, and the second evaporation material is zinc sulfide.

Magnesium fluoride and zinc sulfide have different refractive indices. When the two materials are alternately arranged in layers, light will be reflected and refracted on each interface to achieve a magical effect.

In a preferred embodiment, the first coating layer is magnesium fluoride, the second coating layer is zinc sulfide, the third coating layer is magnesium fluoride, and the fourth coating layer is zinc sulfide.

Zinc sulfide has a denser structure, higher density and melting point, so the vapor pressure generated by evaporation is lower than that of magnesium fluoride, and the amount of gas adsorption of zinc sulfide is less, so it is used as the second and fourth coating layers to ensure the overall quality of the film.

In a preferred embodiment, wherein performing evaporation operations alternately is specifically:

rotating the substrate holder at a speed of 15 revolutions per minute;

switching on the first evaporation source power supply, to evaporate magnesium fluoride with an evaporation time of 300 seconds;

switching off the first evaporation source power supply and switching on the second evaporation source power supply, to evaporate zinc sulfide with an evaporation time of 300 seconds;

switching off the second evaporation source power supply and switching on the first evaporation source power supply, to evaporate magnesium fluoride with an evaporation time of 300 seconds;

switching off the first evaporation source power supply and switching on the second evaporation source power supply, to evaporate zinc sulfide with an evaporation time of 300 seconds;

wherein in the evaporation operations, the shutter is sequentially shielded in front of an evaporation source whose power is disconnected under an action of a driving part.

In a preferred embodiment, a thickness of each of the first, the second, the third, and the fourth coating layer is 0.02 μm.

By controlling the film thickness, the reflections of all interfaces can be superimposed, so that the colorful film can form a high-reflectivity film.

In a preferred embodiment, the vacuum degree in the evaporation chamber reaches 0.003 Pa after the fine vacuuming.

In a preferred embodiment, after the evaporation operations are completed, the vacuum degree in the evaporation chamber is continuously maintained at 0.003 Pa.

In a preferred embodiment, the step of performing a fine vacuuming uses a mechanical pump.

In a preferred embodiment, the step of performing a fine vacuuming uses a diffusion pump in conjunction with a mechanical pump.

The diffusion pump can make the evaporation chamber reach a high degree of vacuum with the cooperation of the mechanical pump, so as to ensure the quality of the evaporation.

In a preferred embodiment, turning on cooled water and compressed air of a vacuum system before performing the fine vacuuming, and then turning on the diffusion pump and heating to 230° C.

Compared with the prior art, the present disclosure has the following beneficial effects:

By implementing the method for vacuum coating a colorful film provided by the present disclosure, the finished film can obtain four coating layers, and the coating materials of two adjacent layers are different and have different refraction. The light is reflected and refracted on each interface, so that the finished film becomes a high-reflection film, so that the coated product can obtain a magical effect with rich and gorgeous colors. In the present disclosure, magnesium fluoride and zinc sulfide are adopted as evaporation materials, and alternate evaporation is carried out. The process is simple. The finished product film can obtain a dense structure, high bonding force, and good colorful effect. The present disclosure has simple process, can provide a good evaporation environment for evaporation, and the quality of evaporation can be guaranteed.

### DESCRIPTION OF EMBODIMENTS

The present disclosure will be further described below in combination with the embodiments:

The present embodiment provides a method for vacuum coating a colorful film, a high vacuum coating machine may be adopted for evaporation. The high vacuum coating machine may include an evaporation chamber, a vacuum system, and an optical detection system. The evaporation chamber may be provided with at least one substrate holder, a first evaporation source and a second evaporation source.

The specific evaporation process can be as follows:

turning on the cooled water and compressed air of the vacuum system, then turning on the diffusion pump and heating to 230° C., to make the vacuum system in the best state, such that it can be prepared for subsequent vacuuming, and ensure the vacuuming effect.

cleaning the substrate;

During the cleaning process, it is not allowed that the staff directly touches the substrate with their hands. They need to wear gloves for operation to avoid contamination of the substrate. A soft gauze cloth may be adopted to dip the acetone to scrub the substrate and degrease the surface of the substrate, and then the substrate is dehydrated with absolute ethanol, dried with a white silk cloth, and covered in a container for later use. The object of cleaning the substrate is to clean the substrate and remove the moisture on the surface of the substrate, thereby strengthening bonding force of the film base.

cleaning and preparing the evaporation chamber;

The dusts inside the evaporation chamber may be removed with a vacuum cleaner, and then the inside of the evaporation chamber and the substrate holder may be wiped with acetone and absolute ethanol in turn. The above operations are all for providing a clean environment for the evaporation coating, so as to prevent the oil, rust, and residual plating materials etc. on the inner wall of the evaporation chamber and the substrate holder from easily evaporating in the vacuum, which affects the purity and bonding force of the film. Tweezers may be adopted to place the cleaned substrate on the substrate holder, the substrate faces two evaporation sources, and the two evaporation sources may be arranged side by side. Then the first evaporation material may be placed on the first evaporation source, and the second evaporation material may be placed on the second evaporation source. A shutter may be arranged between the first and the second evaporation sources; the evaporation chamber is closed to form a closed evaporation space. Before closing the evaporation chamber, the door rubber ring may be wiped with absolute ethanol.

In the embodiment, the first evaporation material may be magnesium fluoride, and the second evaporation material may be zinc sulfide. Magnesium fluoride and zinc sulfide have different refractive indexes. When the two materials are alternately layered, the light can be reflected and refracted on each interface to achieve a magical effect. The dosages of magnesium fluoride and zinc sulfide may be both 3 grams.

pre-vacuuming; turning on the mechanical pump to pump the enclosed evaporation chamber and diffusion pump, so that the vacuum degree of the evaporation chamber reaches 0.3 Pa.

performing ion cleaning;

In a vacuum environment of 0.3 Pa, argon gas may be filled into the evaporation chamber, and the substrate may be ion bombarded under a high pressure of 5000V, and the bombardment time may be 10 minutes. During the ion bombardment process, the substrate holder rotates, with a rotation speed of 15 revolutions per minute. Ion cleaning the substrate before coating can maintain the chemical purity of the substrate, ensure the coating effect, and will not produce a damage layer on the surface, and the surface quality may be guaranteed. Because it is carried out in a vacuum, the environment will not polluted, and it can be ensured that the substrate is not contaminated twice.

performing a fine vacuuming;

A diffusion pump in conjunction with a mechanical pump is adopted to pump the enclosed evaporation chamber again, so that the vacuum degree in the evaporation chamber reaches 0.003 Pa, increasing the vacuum in the evaporation chamber can effectively improve the purity of the film and the bonding force with the film base, and the appropriate vacuum degree can greatly reduce the evaporation temperature of the evaporation material, and improve the evaporation efficiency.

performing evaporation operations;

Magnesium fluoride and zinc sulfide may be pre-melted. Low-power of electricity may be switched on to the evaporation source, magnesium fluoride and zinc sulfide are pre-melted with a pre-melting time of 60 seconds and a pre-melting temperature of 1200° C. Then a higher power of electricity is switched on, the evaporation material may be quickly heated to the vaporization temperature, and then alternate evaporation operations may be performed. The heating method used in the embodiment may be electron beam heating, and the total duration of evaporation operations may be 1200 seconds.

The alternate evaporation process may be as follows:

rotating the substrate holder at a speed of 15 revolutions per minute; switching on the first evaporation source power supply to evaporate the magnesium fluoride with the evaporation time of 300 seconds; switching off the first evaporation source power supply and switching on the second evaporation source power supply, to evaporate zinc sulfide with the evaporation time of 300 seconds; switching off the second evaporation source power supply and switching on the first evaporation source power supply, to evaporate magnesium fluoride with the evaporation time of 300 seconds; switching off the first evaporation source power supply and switching on the second evaporation source power supply, to evaporate zinc sulfide with the evaporation time of 300 seconds. In the above process, the shutter may be sequentially shielded in front of the evaporation sources with the power off under the drive of the corner cylinder, to block the evaporation materials that do not need work to prevent pollution and ensure the purity of each film layer.

completing the evaporation operations;

After the evaporation is completed, the vacuum in the evaporation chamber may be maintained at 0.003 Pa, and the substrate may be placed in the evaporation chamber for 10 minutes to stabilize the film in a high vacuum environment. Then the systems may be closed, the evaporation chamber may be inflated, so as to balance the air pressure inside and outside the evaporation chamber, and the substrate can be taken out.

The film after the evaporation is completed may comprise four layers, that is a first coating layer, a second coating layer, a third coating layer, and a fourth coating layer in order. The first coating layer may be magnesium fluoride, the second coating layer may be zinc sulfide, and the third coating layer may be magnesium fluoride, and the fourth coating layer may be zinc sulfide. Magnesium fluoride and zinc sulfide have different refractive indices. When the two kinds of the coating layers are alternately arranged in layers, light will be reflected and refracted on each layer to achieve a colorful effect. Each of the four-layer film has a thickness of 0.02 μm. In the embodiment, the optical detection system may be used to monitor the layer thickness online, and the reflection signal of the reference light source may be measured to monitor the layer thickness and control the conversion of the evaporation material. The control of the layer thickness can superimpose the reflections of all interfaces, so that the colorful film forms a high reflectivity film.

The coating completed by the above method is a high-reflection colorful film with rich and gorgeous color. The total thickness of the film is 0.8 μm, and the test basis is SEM. The film adhesion is 3B, and the test basis is GB/T6739-2006. The test of salt spray resistance≥2 h without abnormality, the test basis is GB/T10125-2012.

The specific embodiments described herein are merely illustrative of the spirit of the present disclosure. Those skilled in the art to which the present disclosure belongs can make various modifications or additions to the specific embodiments described or use similar alternatives, but they will not deviate from the spirit of the present disclosure or exceed the defined range of the appended claims.

What is claimed is:

1. A method for vacuum coating a colorful film, comprising the following steps:
Step 1: pre-treating a substrate;
scrubbing the substrate with acetone, dehydrating the substrate with absolute ethanol, and then drying the substrate for later use;
Step 2: cleaning an evaporation chamber;
removing dusts from the evaporation chamber, and then scrubbing an inside of the evaporation chamber with the acetone and alcohol;
Step 3: placing the substrate and evaporation sources;
placing the substrate on a substrate holder, placing a first evaporation material on a first evaporation source, and placing a second evaporation material on a second evaporation source, providing a shutter between the first evaporation source and the second evaporation source, closing the evaporation chamber to form an enclosed evaporation space;
Step 4: performing a pre-vacuuming;
turning on an exhaust pump to exhaust the enclosed evaporation chamber, so that a vacuum degree of the evaporation chamber reaches 0.2-0.4 Pa;
Step 5: performing an ion cleaning;
filling the evaporation chamber with argon gas, and performing ion bombardment on the substrate under a high pressure of 5000V with a bombardment time of 5-10 min; rotating the substrate holder during an ion bombardment process;
Step 6: performing a fine vacuuming;
pumping the enclosed evaporation chamber again by using an air pump, to make the vacuum degree in the evaporation chamber reach 0.001-0.003 Pa;
Step 7: performing evaporation operations;
pre-melting the first evaporation material and the second evaporation material with a pre-melting time of 50-60 seconds and a pre-melting temperature of 1000-1200° C.; performing evaporation operations alternately after pre-melting, with a total time of the evaporation operation of 1000-1200 seconds;
Step 8: completing the evaporation operations;
placing the substrate in the evaporation chamber for 8-12 minutes after the evaporation operations are completed, and then closing each system; inflating the evaporation chamber, to balance air pressures inside and outside the evaporation chamber; taking out the substrate;
wherein a finished film has four layers, from an inside to an outside, the four layers comprises a first coating layer, a second coating layer, a third coating layer and a fourth coating layer; the first coating layer and the third coating layer have a same material, and the second coating layer and the fourth coating layer have another same material.

2. The method for vacuum coating a colorful film according to claim 1, wherein the first evaporation material is magnesium fluoride, and the second evaporation material is zinc sulfide.

3. The colorful film vacuum coating method according to claim 2, wherein the first coating layer is magnesium fluoride, the second coating layer is zinc sulfide, the third coating layer is magnesium fluoride, and the fourth coating layer is zinc sulfide.

4. The method for vacuum coating a colorful film according to claim 2, wherein performing evaporation operations alternately is specifically:
rotating the substrate holder at a speed of 15 revolutions per minute;
switching on the first evaporation source power supply, to evaporate magnesium fluoride with an evaporation time of 300 seconds;
switching off the first evaporation source power supply and switching on the second evaporation source power supply, to evaporate zinc sulfide with an evaporation time of 300 seconds;
switching off the second evaporation source power supply and switching on the first evaporation source power supply, to evaporate magnesium fluoride with an evaporation time of 300 seconds;
switching off the first evaporation source power supply and switching on the second evaporation source power supply, to evaporate zinc sulfide with an evaporation time of 300 seconds;
wherein in the evaporation operations, the shutter is sequentially shielded in front of an evaporation source whose power is disconnected under an action of a driving part.

5. The method for vacuum coating a colorful film according to claim 1, wherein a thickness of each of the first, the second, the third, and the fourth coating layer is 0.02 μm.

6. The method for vacuum coating a colorful film according to claim 5, wherein the vacuum degree in the evaporation chamber reaches 0.003 Pa after the fine vacuuming

7. The method for vacuum coating a colorful film according to claim 6, wherein, after the evaporation operations are completed, the vacuum degree in the evaporation chamber is continuously maintained at 0.003 Pa.

8. The method for vacuum coating a colorful film according to claim 6, wherein the step of performing a fine vacuuming uses a diffusion pump in conjunction with a mechanical pump.

9. The method for vacuum coating a colorful film according to claim 8, wherein, turning on cooled water and compressed air of a vacuum system before performing the fine vacuuming, and then turning on the diffusion pump and heating to 230° C.
